(19) United States
(12) Patent Application Publication
(10) Pub. No.: US 2026/0052631 A1
(43) Pub. Date: Feb. 19, 2026

(54) MULTI-LAYER, MULTI BOARD BUS BAR

(71) Applicant: Caterpillar Inc., Peoria, IL (US)

(72) Inventors: Basheer Qattum, Peoria, IL (US); Dachaun Yu, Dunlap, IL (US)

(73) Assignee: Caterpillar Inc., Peoria, IL (US)

(21) Appl. No.: 18/803,012

(22) Filed: Aug. 13, 2024

(51) Int. Cl. H05K 1/14; H02M 7/00; H05K 3/36

(52) U.S. Cl. CPC H05K 1/144; H02M 7/003; H05K 3/36; H05K 2201/041

(57) ABSTRACT

A composite bus bar for power converters is disclosed. The composite bar comprises a first printed circuit board having a first insulation layer between a first conductive layer and a second conductive layer, and a second printed circuit board having a second insulation layer between a third conductive layer and a fourth conductive layer. The first printed circuit board and the second printed circuit board are arranged in an electrically parallel configuration.

### TECHNICAL FIELD

The present disclosure generally relates to power transmission systems and more particularly to multi-layer, multi-board bus bars used in AC/DC inverters, converters, and high-power electrical applications.

### BACKGROUND

Power conversion systems are critical in numerous applications, ranging from renewable energy systems to industrial machinery and transportation. These systems often require efficient management of electrical energy through various stages of conversion, which involves the transformation of electrical power from one form to another, such as from direct current (DC) to alternating current (AC), or vice versa. A key component in such power conversion systems is the DC link, which serves to store and stabilize energy between the stages of conversion, ensuring smooth and efficient operation.

Traditionally, DC links have employed bulky and expensive copper bus bars to manage high current loads. These copper bus bars, while effective, present several challenges, including high cost, significant weight, and complex manufacturing processes. The trend in power electronics is to seek alternatives that reduce cost and improve performance without compromising reliability. One such alternative that has gained attention is the use of printed circuit boards (PCBs) to replace traditional bus bars. PCBs offer advantages such as reduced weight, lower cost, and ease of integration into existing electronic systems.

Recent advancements in multilayer PCB technology have further enhanced their application in high-power electronics. Multilayer PCBs can be designed to handle substantial current loads while maintaining a compact and lightweight form factor. These PCBs can be arranged in various configurations to optimize their electrical and thermal performance, making them suitable for use in sophisticated power conversion systems.

Others have attempted to design bus bars for power converters. For example, US10701795B2, discloses a direct current link bus for a power converter that utilizes a multi-layered printed circuit board arranged in a parallel connection. This reference highlights the benefits of using multi-layered PCBs with sets of positive and negative link connectors coupled perpendicular to the first and second set of layers, respectively, to define a positive bus and a negative bus.

It can therefore be seen that a need exists for improved bus bar designs with multiple PC boards sandwiched together in an electrically-parallel configuration that can further optimize cost, performance, and thermal management in DC power conversion systems.

### SUMMARY

In accordance with one aspect of the disclosure, a composite bus bar for power converters is disclosed. The composite bar comprises a first printed circuit board having a first insulation layer between a first conductive layer and a second conductive layer, and a second printed circuit board having a second insulation layer between a third conductive layer and a fourth conductive layer. The first printed circuit board and the second printed circuit board are arranged in an electrically parallel configuration.

In accordance with another aspect of the disclosure, a power converter is disclosed. The power converter comprises a shell, power electronics in the shell, and a multi-layer, multi-board bus bar for power converters is disclosed. A first printed circuit board (“first PCB”) including an insulation layer between a first conductive layer and a second conductive layer; a second printed circuit board (“second PCB”) including a second insulation layer between a third conductive layer and a fourth conductive layer; and the first PCB and the second PCB are coupled together.

In accordance with another aspect of the disclosure, a method of assembling a composite bus bar is disclosed. The method comprises the steps of: providing a first printed circuit board and a second printed circuit board each including a center board between a first conductive layer and a second conductive layer; and coupling the first printed circuit board and the second printed circuit board together

These and other aspects and features of the present disclosure will be better understood upon reading the following detailed description when read in conjunction with the accompanying drawings.

### BRIEF DESCRIPTION OF THE DRAWINGS

FIG. 1 is a perspective schematic of a power converter, according to an embodiment of the disclosure.

FIG. 2 is a schematic of a multi-layer, multi-board bus bar, according to an embodiment of the disclosure.

FIG. 3 is a schematic of a multi-layer, multi-board bus bar, according to an embodiment of the disclosure.

FIG. 4 is a flow-chart of a method of assembling a composite bus bar, according to an embodiment of the disclosure.

The figures depict one embodiment of the presented invention for purposes of illustration only. One skilled in the art will readily recognize from the following discussion that alternative embodiments of the structures and methods illustrated herein may be employed without departing from the principles described herein.

### DETAILED DESCRIPTION

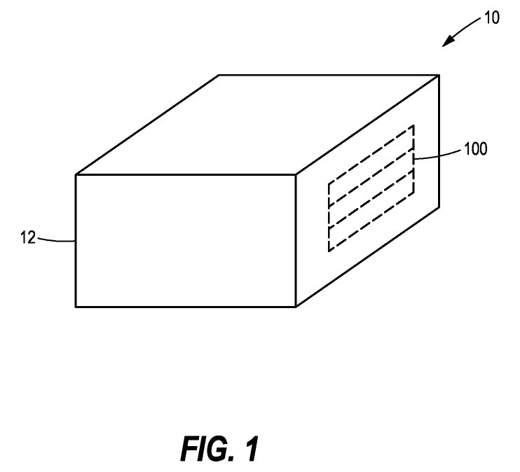

Referring now to the drawings, and with specific reference to the depicted example in FIG. 1, a power converter 10 comprising a composite bus bar 100 is illustrated. The composite bus bar 100 is a multi-layer, multi-board bus bar configured to integrate into a variety of power transmitter systems and applications, such as an AC/DC inverter or a power converter 10. Power transmitters are essential for managing and converting electrical energy in various applications, including industrial machinery, renewable energy systems, and transportation. While the following detailed description describes an exemplary aspect in connection with an AC/DC inverter power converter, it should be appreciated that the description applies equally to the use of the present disclosure in other power systems, including, but not limited to, uninterruptible power supplies (UPS), generator sets, and other high-power electrical systems.

Referring now to FIG. 1, the power converter 10 is illustrated, according to an embodiment of the disclosure. The power converter 10 may comprise a composite bus bar 100 plurality of power electronics and the, also referred to as a multi-layer, multi-board bus bar. The composite bus bar 100 includes multiple layers of conductive and insulating materials laminated together to form a compact and efficient power distribution network. This structure minimizes inductance and resistance, which are critical parameters in high-power applications.

The composite bus bar 100 integrates various components, such as capacitors, inductors, and power semiconductors, directly onto its layers. This integration helps in reducing the overall footprint of the power converter 10 and enhances its thermal management capabilities. Additionally, the multi-layer design allows for better control of electrical parameters, contributing to improved performance and reliability of the power converter 10.

In the depicted example, the power converter 10 is designed to convert AC power to DC power. The AC input is connected to the primary side of the power converter 10, where it undergoes rectification and filtering processes. The rectified DC power is then transmitted through the composite bus bar 100 to the secondary side, where it is further processed to achieve the desired DC output voltage and current levels.

The composite bus bar 100 is designed to handle high current densities and operate efficiently under various load conditions. Its design includes multiple conductive paths and layers of insulation to ensure electrical isolation and safety. The construction materials for the composite bus bar 100 are chosen for their electrical conductivity and thermal properties, enabling effective heat dissipation and maintaining stable operation even under high-power conditions.

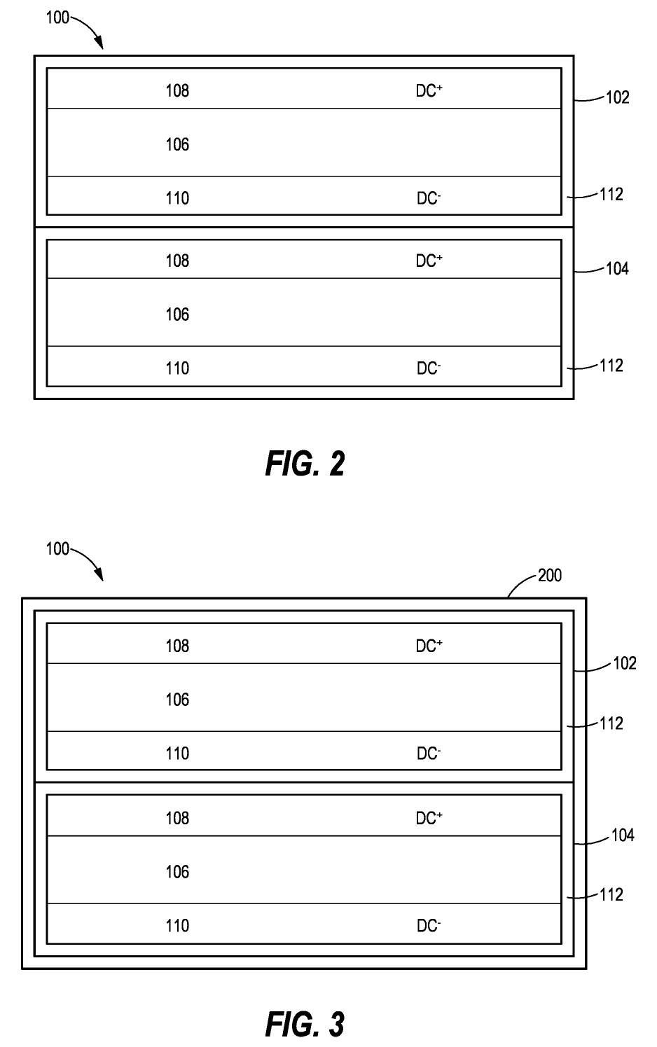

Referring now to FIG. 2, a schematic diagram illustrates the composite bus bar 100, according to an embodiment of the disclosure. The composite bus bar 100 is designed to handle high current loads by increasing the number of copper layers within the assembly.

The composite bus bar 100 comprises a first printed circuit board 102 and a second printed circuit board 104. Each printed circuit board includes a center board 106 that is sandwiched between two lamination layers. The first printed circuit board 102 includes a first conductive layer 108 with a positive electric charge on one side of the center board 106, and a second conductive layer 110 with a negative electric charge on the opposite side of the center board 106.

Similarly, the second printed circuit board 104 includes the first conductive layer 108 with a positive electric charge and the second conductive layer 110 with a negative electric charge. This configuration ensures a balanced distribution of electrical charges across the layers, minimizing potential imbalances and enhancing overall performance.

The first conductive layer 108 and the second conductive layer 110 may be made of copper, which facilitates efficient electrical conduction while providing the necessary insulation between layers to prevent short circuits. The first conductive layer 108, the center board 106, and the second conductive layer 110 may be formed together by a third conductive layer 112 encapsulating each to form the first printed circuit board 102 and/or the second printed circuit board 104.

By coupling the first printed circuit board 102 and the second printed circuit board 104 together, the invention achieves a multi-layer, multi-board configuration that allows for a greater amount of current-carrying copper than a single-layer board, thereby overcoming the copper ounce limit typically encountered in conventional printed circuit boards. This multi-layer approach significantly increases the current-carrying capacity of the composite bus bar 100, making it capable of handling higher power loads with minimal losses.

Referring now to FIG. 3, a schematic diagram illustrates the composite bus bar 100, according to another embodiment of the disclosure. A fourth conductive layer 200 may be provided around the composite bus bar 100 to couple the first printed circuit board 102 and the second printed circuit board 104 together.

This multi-board approach results in a multi-layer, multi-board DC link bus bar as the composite bus bar 100 that can handle higher power values without the need for expensive fully-laminated copper bus bars. The composite bus bar 100 significantly reduces costs while maintaining high performance and reliability in power transmission systems such as AC/DC inverters and converters. The stacked configuration of the printed circuit boards not only increases the current-carrying capacity but also enhances the overall thermal management of the composite bus bar 100, making it suitable for various high-power applications.

Additionally, the composite bus bar 100 offers flexibility in design and manufacturing. The modular nature of the multi-board assembly allows for easy customization and scalability, enabling designers to tailor the bus bar to specific power requirements and system configurations. This adaptability is particularly beneficial in applications where space constraints and power density are critical considerations.

The design of the composite bus bar 100 also contributes to its durability and longevity. The use of high-quality materials and advanced manufacturing techniques ensures that the composite bus bar 100 can withstand harsh operating conditions and mechanical stresses commonly encountered in industrial environments. This robustness translates to reduced maintenance needs and longer service life, providing a reliable solution for demanding power applications.

### INDUSTRIAL APPLICABILITY

In operation, the present disclosure may find applicability in many industries including, but not limited to, power transmission systems and high-power electrical applications, including industrial machinery, renewable energy systems, and transportation. While the foregoing detailed description is made with specific reference to AC/DC power converters, it is to be understood that its teachings may also be applied onto the other machines such as power transmitters, inverters, uninterruptible power supplies (UPS), generator sets, and other high-power electrical systems.

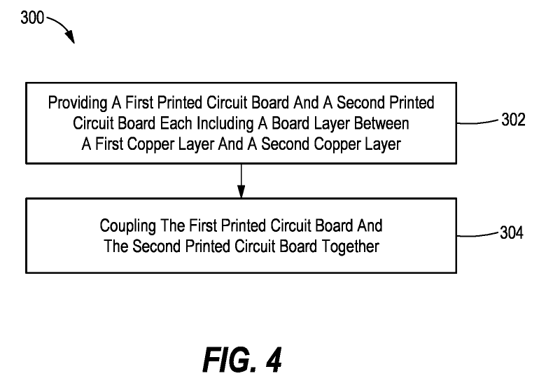

Now referring to FIG. 4, a method 300 of assembling the composite bus bar 100 is disclosed, according to an embodiment of the disclosure. In a step 302, the method 300 involves providing a first printed circuit board 102 and a second printed circuit board 104, each including a center board 106 made of FR4 material between a first conductive layer 108 and a second conductive layer 110, both conductive layers may be made of copper.

In a step 304, a first printed circuit board 102 and a second printed circuit board 104 are coupled together. The first printed circuit board 102 and a second printed circuit board 104 may be arranged in an electrically parallel configuration.

In a step 304, the first printed circuit board 102 and the second printed circuit board 104 are coupled together, which may include applying an adhesive between them, bolting together, sandwiching together, and the like, as generally known in the arts.

A laminate structure may be applied around the coupled printed circuit boards to enhance thermal management and reduce loop inductants. Additionally, the first conductive layer 108 forms an electrically positive layer, DC+, and the second conductive layer 110 forms an electrically negative layer, DC-. This configuration ensures a clear separation of the positive and negative paths, minimizing the risk of short circuits and enhancing the overall safety and reliability of the composite bus bar 100.

The method 300 offers significant advantages in terms of reducing the cost and complexity of traditional bus bars while enhancing performance and thermal management in various industrial applications.

From the foregoing, it can be seen that the technology disclosed herein has industrial applicability in a variety of settings such as, but not limited to power transmission systems, requiring efficient and cost-effective DC link bus bar, generator sets and other devices requiring reliable power management and conversion.

What is claimed is:

1. A composite bus bar, comprising:
a first printed circuit board (“first PCB”) having a first conductive layer between a first copper layer and a second conductive layer; a second printed circuit board (“second PCB”) having a second conductive layer between a third conductive layer and a fourth conductive layer; the first PCB and the second PCB are arranged in an electrically parallel configuration.

2. The composite bus bar of claim 1, further comprising an conductive layer positioned between the first PCB and the second PCB.

3. The composite bus bar of claim 1, wherein the first conductive layer and the third conductive layer forms a DC positive layer and the second conductive layer and the fourth conductive layer forms a DC negative layer.

4. The composite bus bar of claim 1, further comprising a laminate structure around the first PCB and the second PCB.

5. The composite bus bar of claim 1, wherein the composite bus bar is configured for use in an AC/DC inverter.

6. The composite bus bar of claim 1, wherein the composite bus bar is configured for use in an uninterruptible power supply (UPS) system.

7. The composite bus bar of claim 1, wherein the center board made of FR4 insulation material.

8. A power converter comprising:
a shell; power electronics in the shell; and a multi-layer, multi-board bus bar including:
a first printed circuit board (“first PCB”) including an insulation layer between a first conductive layer and a second conductive layer; a second printed circuit board (“second PCB”) including a second insulation layer between a third conductive layer and a fourth conductive layer; and the first PCB and the second PCB are coupled together.

9. The power converter of claim 8, wherein:
the first PCB and the second PCB are coupled together in an electrically parallel arrangement to form a multi-layer multi-board DC link bus bar.

10. The power converter of claim 8, wherein the first conductive layer and the third conductive layer forms a DC positive layer and the second conductive layer and the fourth conductive layer forms a DC negative layer.

11. The power converter of claim 8, wherein the first PCB and the second PCB are coupled using one chosen from a group consisting of an adhesive, mechanical fasteners, bolts, a lamination, and a glue.

12. The power converter of claim 8, further comprising a laminate structure coupling the first PCB and the second PCB.

13. The power converter of claim 8, wherein the power converter is one chosen from a group consisting of: an inverter, a generator set with AC bus bars, and an uninterruptible power supply (UPS) system.

14. The power converter of claim 8, wherein the insulation layer is made of FR4 material.

15. A method of assembling a composite bus bar, comprising:
providing a first printed circuit board and a second printed circuit board each including a center board between a first conductive layer and a second conductive layer; and coupling the first printed circuit board and the second printed circuit board together.

16. The method of claim 15, further comprising arranging the first printed circuit board and the second printed circuit board in an electrically parallel configuration.

17. The method of claim 15, further comprising a conductive lamination around the first printed circuit board and the second printed circuit board.

18. The method of claim 15, further comprising coupling by applying an adhesive between the first printed circuit board and the second printed circuit board.

19. The method of claim 15, wherein the first conductive layer forms an electrically positive layer and the second conductive layer forms an electrically negative layer.

20. The method of claim 15, wherein the center board is made of FR4 material.
